(19) United States
(12) Patent Application Publication
(10) Pub. No.: US 2013/0324771 A1
(43) Pub. Date: Dec. 5, 2013

(54) NOVEL BENZOPYRENE COMPOUND AND ORGANIC LIGHT-EMITTING DEVICE HAVING THE SAME

(71) Applicant: CANON KABUSHIKI KAISHA, Tokyo (JP)

(72) Inventors: Naoki Yamada, Inagi-shi (JP); Jun Kamatani, Tokyo (JP); Kengo Kishino, Tokyo (JP); Akihito Saitoh, Gotemba-shi (JP)

(21) Appl. No.: 13/908,284

(22) Filed: Jun. 3, 2013

(30) Foreign Application Priority Data
Jun. 5, 2012 (JP) 2012-128281

(51) Int. Cl. C07C 13/465; H01L 29/08

(52) U.S. Cl. CPC H01L 51/0055; G03G 15/04036
USPC 585/27; 257/40

(57) ABSTRACT

The present invention provides a novel benzopyrene compound and also provides a organic light-emitting device. The present invention provides a benzopyrene represented by the formula [1] above.

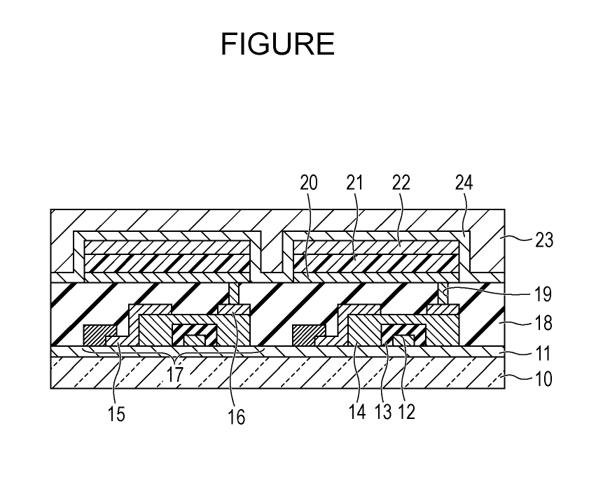

### BACKGROUND OF THE INVENTION

1. Field of the Invention

The present invention relates to a benzopyrene compound and an organic light-emitting device including the benzopyrene compound.

2. Description of the Related Art

An organic light-emitting device includes a pair of electrodes and an organic compound layer disposed therebetween. A light-emitting organic compound in the light-emitting layer generates excitons by injection of electrons and holes through the pair of electrodes, and light is emitted when the excitons return to their ground state.

Patent Literature 1 describes the organic compound having a benzo[e]pyrene backbone as this structural formula A shown below and the organic light-emitting device having the compound.

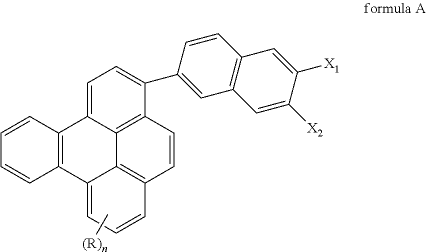

In the formula, X1 and X2 represent respectively a hydrogen atom, a substituted or unsubstituted aryl group. One of X1 and X2 represents the subtitled or unsubstituted aryl group. R

R represents an alkyl group. And n represents 0 or 1.

Patent Literature 1 describes the compound of the formula A has band gap suitable for the organic light-emitting device as the compound has the naphtyl group as seen in the formula.

And Patent Literature 1 also describes that the benzo[e]pyrene backbone in itself has too wide band gap and that even if the benzo[e]pyrene backbone has an alkyl group or a phenyl group, it has too wide band gap.

And Patent Literature 1 also describes the compound of formula A is used as a host material for the organic light-emitting device which emits blue light.

### CITATION LIST

### Patent Literature

PTL 1 Japan laid open patent No. 2011-213649 (formula 1, paragraph 0028, 0029, example 8)

### SUMMARY OF THE INVENTION

Aspects of the present invention provide a benzo pyrene compound represented by the following formula [1]:

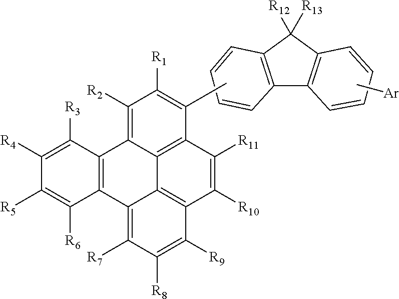

wherein in formula [1], R1 to R13 each independently indicate a hydrogen atom and an alkyl group having 1 to 4 carbon atoms;

Ar is selected from a group of a phenyl group, a biphenyl group, a terphenyl group, a fluorenyl group, a naphthyl group and a phenanthlyl group.

The hydrogen atom of Ar may be substituted by an alkyl group having 1 to 4 carbon atoms.

Further features of the present invention will become apparent from the following description of exemplary embodiments (with reference to the attached drawings).

### BRIEF DESCRIPTION OF THE DRAWINGS

FIGURE shows a schematic cross-sectional view illustrating organic light-emitting devices and switching devices connected to the organic light-emitting devices.

### DESCRIPTION OF THE EMBODIMENTS

The compound represented as structure A in the Patent Literature 1 is a host material which has suitable band gap to the guest material which emit blue light.

Applying a guest material which is to emit red light to the organic light-emitting material with this host material, high voltage is needed. The inventor thinks it is because there is great difference among band gaps of these materials.

The inventor thinks there is room for improvement to provide a new host material which is suitable for the red emitting phosphorescent guest material, in other words, to provide a new host material which transfer energy to the guest material without excessively raising the voltage.

The inventor also thinks that molecular designing of the host material is needed to tune of the band gap and T1 energy level in order to fit for the guest material which emits red phosphorescent light. T1 energy level means the lowest triplet state energy level. To the inventor it is desirable that T1 energy of the host material is higher than that of the phosphorescent material which emits red light and there is no great difference between T1 energy of the host material and that of the phosphorescent material which emits red light.

Aspects of the present invention provide a benzo pyrene compound that has a benzo[e]pyrene backbone. Aspects of the present invention provide a new benzopyrene compound which has band gap and lowest excited triplet level (T1) suitable for a guest material which emits red phosphorescence. In addition, aspects of the present invention provide an organic light-emitting device having the new benzopyrene compound.

### Description of A Benzopyrene Compound of the Embodiment

Aspects of the present invention provide a benzopyrene compound represented by the following formula [1]:

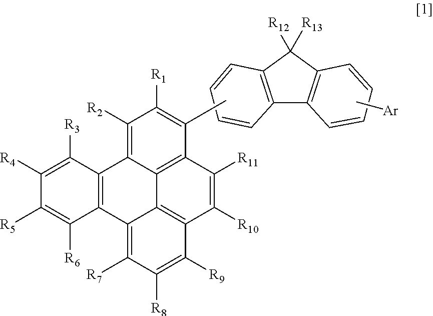

wherein in formula [1], R1 to R13 each independently indicate a hydrogen atom and an alkyl group having 1 to 4 carbon atoms;

Ar is selected from a group of a phenyl group, a biphenyl group, a terphenyl group, a fluorenyl group, a naphthyl group and a phenanthlyl group.

The hydrogen atom of Ar may be substituted by an alkyl group having 1 to 4 carbon atoms.

Examples of the alkyl group having 1 to 4 carbon atoms include methyl groups, ethyl groups, iso-propyl groups, n-propyl groups, sec-butyl groups, and tert-butyl groups.

The benzopyrene compound according to aspects of the present invention, as seen in formula [1], has a bonding between the benzopyrene(benzo[e]pyrene) backbone and a fluorene portion. So that the compound has the band gap of more than 2.90 eV and 3.15 eV or less and has T1 energy level of 530 nm or more and less than 580 nm.

In this embodiment, the material which emits red phosphorescence has band gap of 2.90 eV and has T1 energy level is 580 nm or more and 680 nm or less.

In the case where the benzopyrene compound of one embodiment of the present invention is used as the host material in the light-emitting layer and a material which emits red fluorescence is used as the guest material, it is preferable to transfer energy from the host material to the guest material without high voltage. Transferring energy is so called intersystem crossing.

The inventor thinks this is because the band gap of this benzopyrene compound is wider than that of the guest material. The inventor also thinks this is because the T1 energy level of this benzopyrene compound is higher than that of the guest material.

The band gap and T1 energy level of the benzopyrene backbone itself is 3.30 eV and 538 nm.

The benzopyrene compound according to aspects of the present invention, as seen in formula [1], has a bonding between the benzopyrene backbone and a fluorene portion. So the film of the benzopyrene compound is easy to be obtained. The inventor thinks it is because the benzopyrene compound has higher amorphousness from the bonding.

At least any one of R1 to R11, R12, or R13 of the benzopyrene compound of the present invention, as seen in formula [1], may be substituted for an alkyl group having 1 to 4 carbon atoms. The inventor thinks this substituent improves amorphousness of the bezopyrene compound according to aspects of the present invention. The alkyl group is preferably selected from tert-butyl group or iso-propyl group.

Ar of the benzopyrene compound of the present invention, as seen in formula [1], is described as above. The inventor thinks Ar also give high amorphousness to the benzopyrene compound according to aspects of the present invention. And the species of Ar, which are described above, have wider band gap than that of the benzopyrene backbone.

R12 and R13 of the benzopyrene compound according to aspects of the present invention, as seen in formula [1], may be different from each other, and preferably these are the same substituent, i.e., a methyl group.

Among the benzopyrene compound according to aspects of the present invention, as seen in formula [1], more preferred is the compound represented by formula [2] as below:

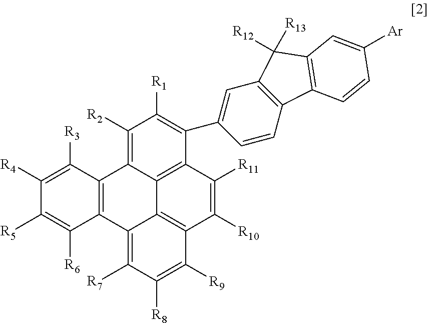

In the formula [2], R1 to R13 and Ar are the same as those described above in the formula [1].

The benzopyrene compound according to aspects of the present invention, as seen in formula [2], the 2-position of the fluorene portion bonds to the benzopyrene backbone and the 7-portion of the fluorene portion bonds to the Ar.

The benzopyrene compound according to aspects of the present invention, as seen in formula [2], has band gap which is more than 2.90 eV and 3.05 or less.

The benzopyrene compound according to aspects of the present invention, as seen in formula [2], has high flatness of the entire molecule and has high mobility of electron or hole.

Table 1 shows two chemical structures and their HOMO levels. The one is the structure of the benzopyrene compound where the benzopyrene backbone bonds to the fluorene portion. And another is the structure of the benzopyrene compound where the benzopyrene backbone bonds to the naphthalene portion.

Comparing these compounds to each other, the benzopyrene compound that has fluorene portion has a smaller absolute value of HOMO level. In other words, HOMO level of the benzopyrene compound that has fluorene portion is nearer to the vacuum level. The inventor thinks the benzopyrene compounds where 1-, 3-, or 4-position of fluorene portion bonds to the benzopyrene backbone has smaller absolute value of HOMO level comparing with the benzopyren compound where naphthalene portion bonds to the benzopyrene backbone.

These of the benzopyrene compounds which are described in formula [1] and [2], have smaller HOMO level as described above, so the hole-injection barrier between the emission layer and the another organic layer, for example, a hole-transporting layer is low. The another organic layer is contacted with the emission layer in the anode side of the emission layer. HOMO level of the another organic layer is −5.90 eV or more and −5.30 or less.

| Compound | HOMO |
|---|---|
| 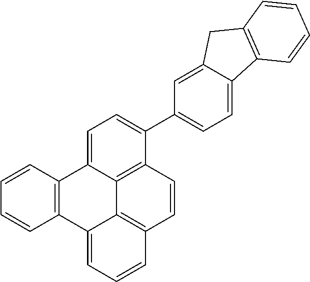 [SMILES: c1ccc2c(c1)Cc1cc(-c3ccc4c5ccccc5c5cccc6ccc3c4c65)ccc1-2] | −5.2528 |
| 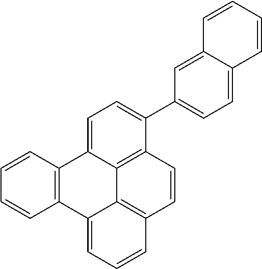 [SMILES: c1ccc2cc(-c3ccc4c5ccccc5c5cccc6ccc3c4c65)ccc2c1] | −5.3135 |

The value of HOMO level is obtained by the molecular orbital calculations.

For the molecular orbital calculation, DFT basis function 6-31+G(d) was applied according to Gaussian 09 (Gaussian 09, Revision A.02, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery,Jr. , J. E. Peralta, F. Ogliaro, M. Bearpark, J. J. Heyd, E. Brothers, K. N. Kudin, V. N. Staroverov, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford, Conn., 2009.). Although it is known that this calculation gives an error, it is useful in designing molecules.

Specific examples of the benzopyrene compound according to aspects of the present invention are shown below, but the present invention is not limited thereto.

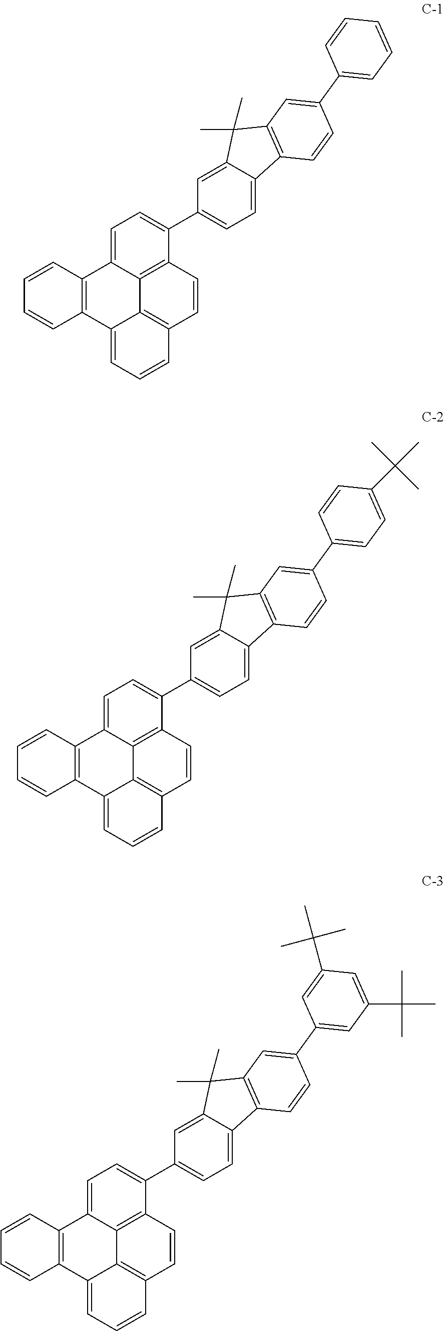

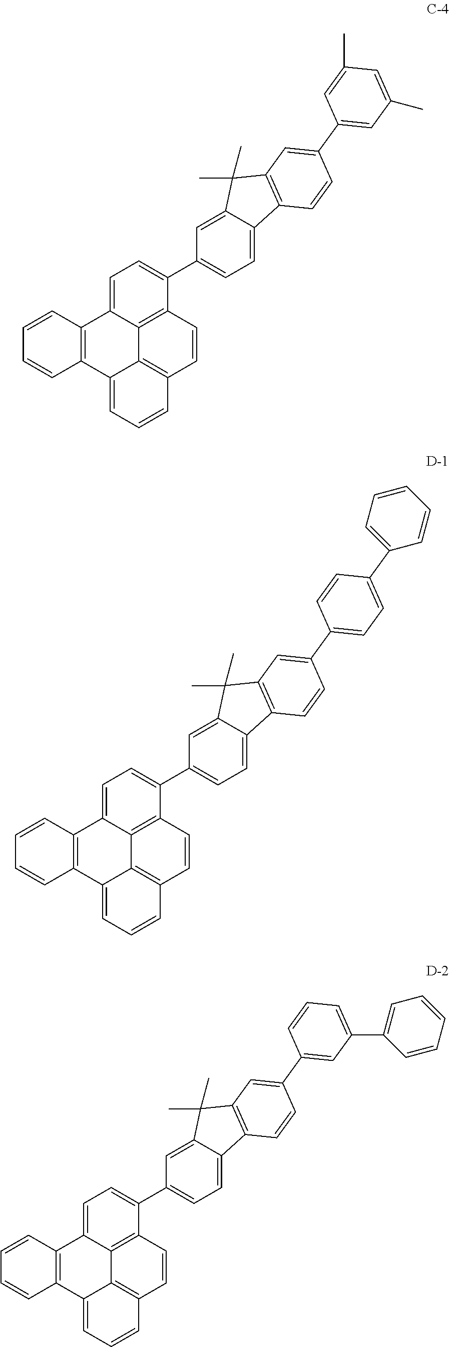

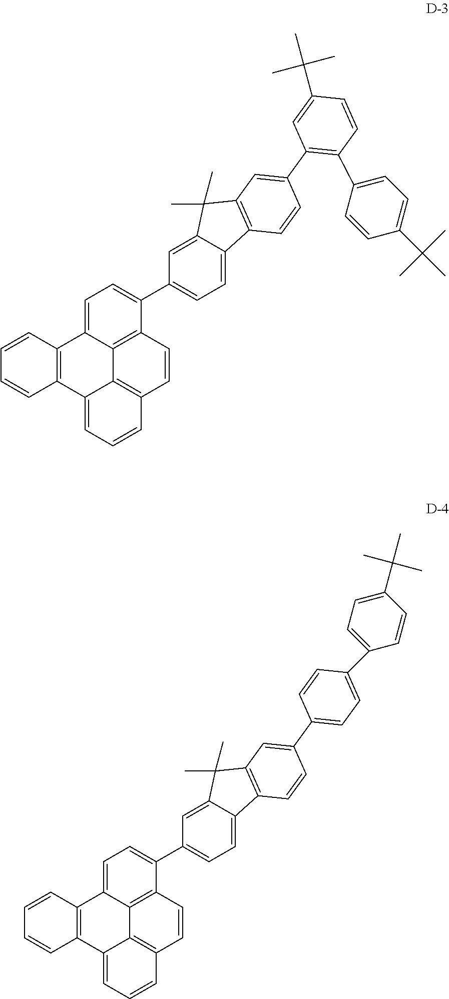

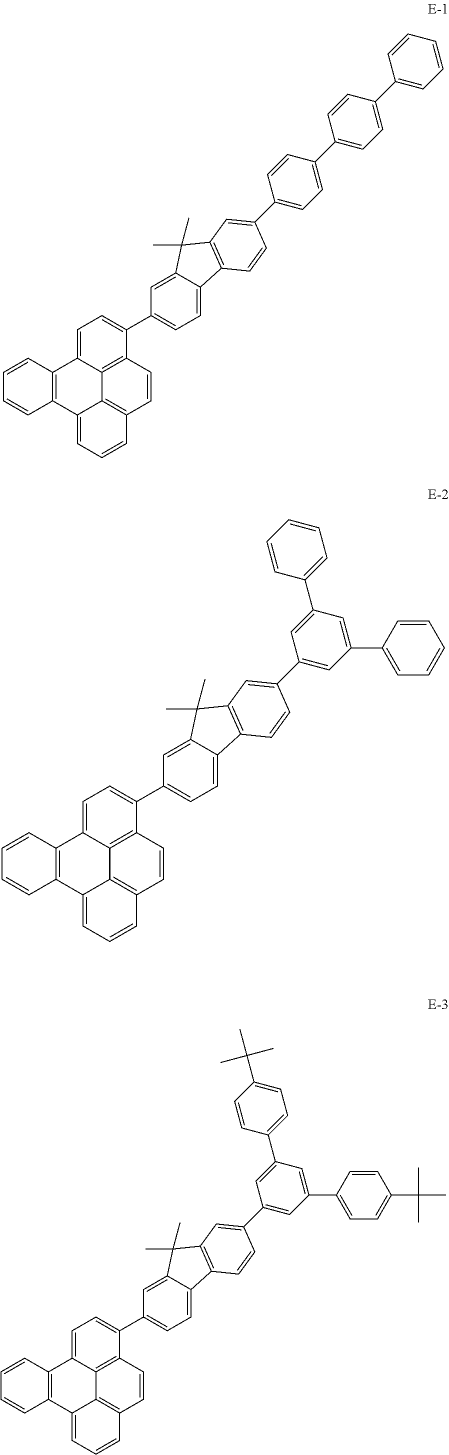

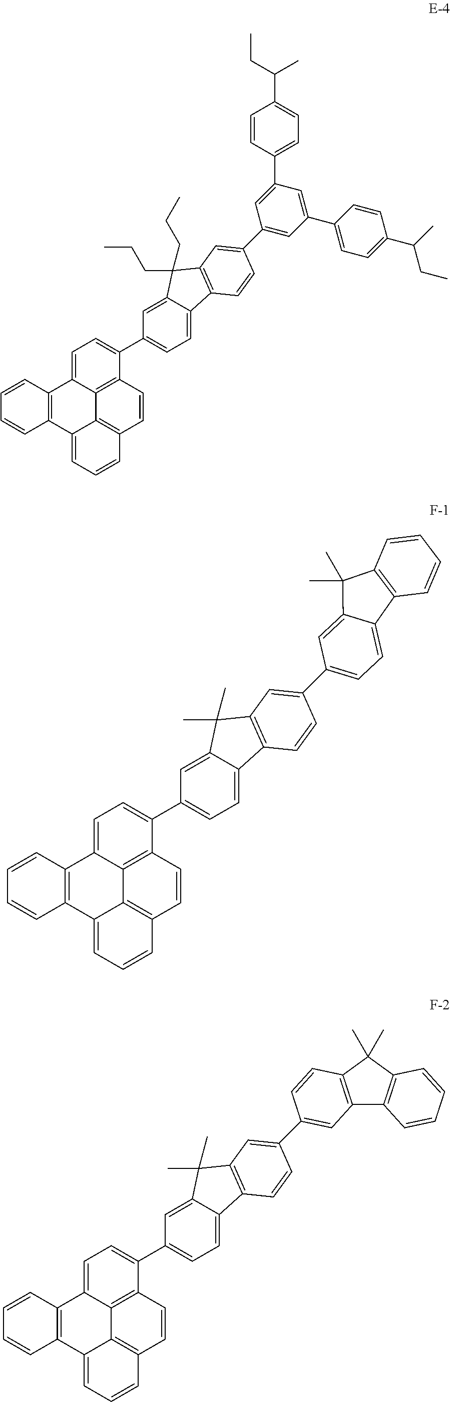

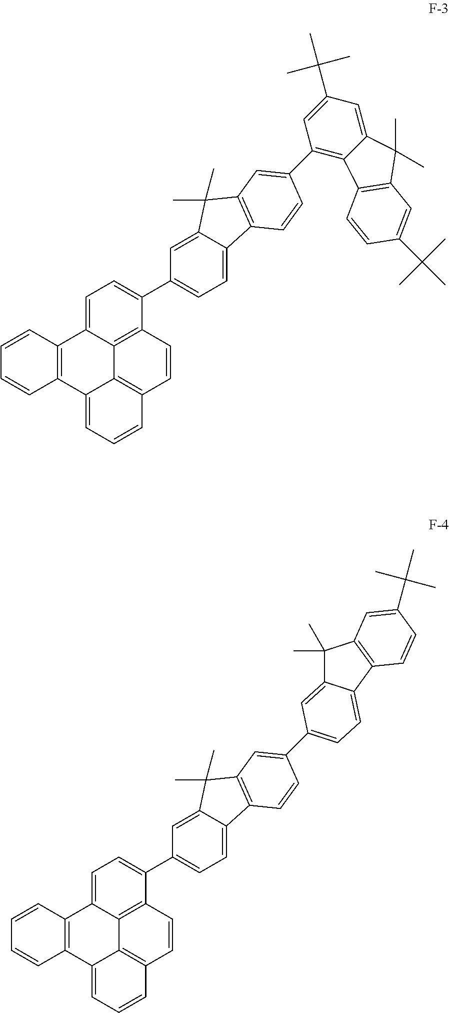

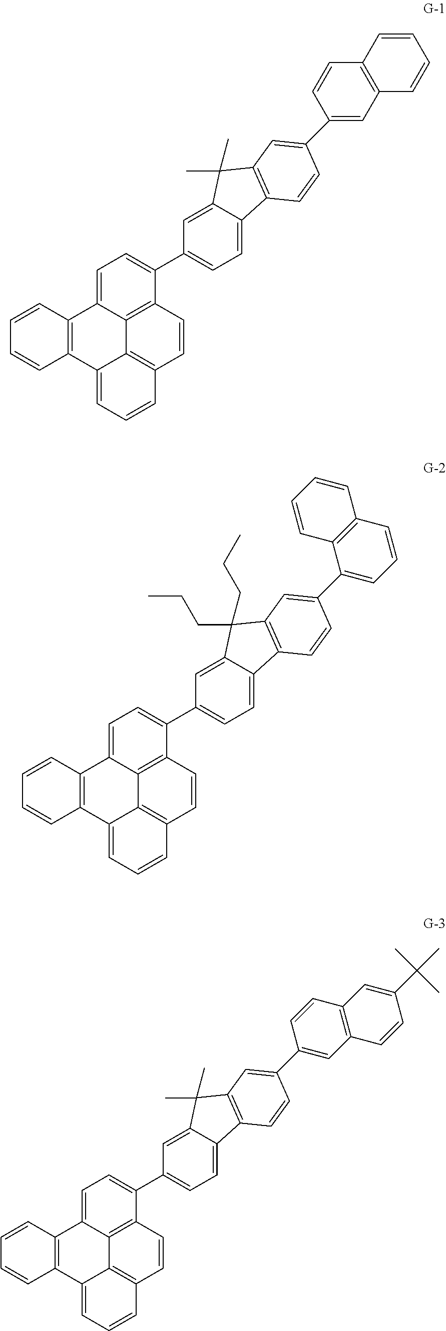

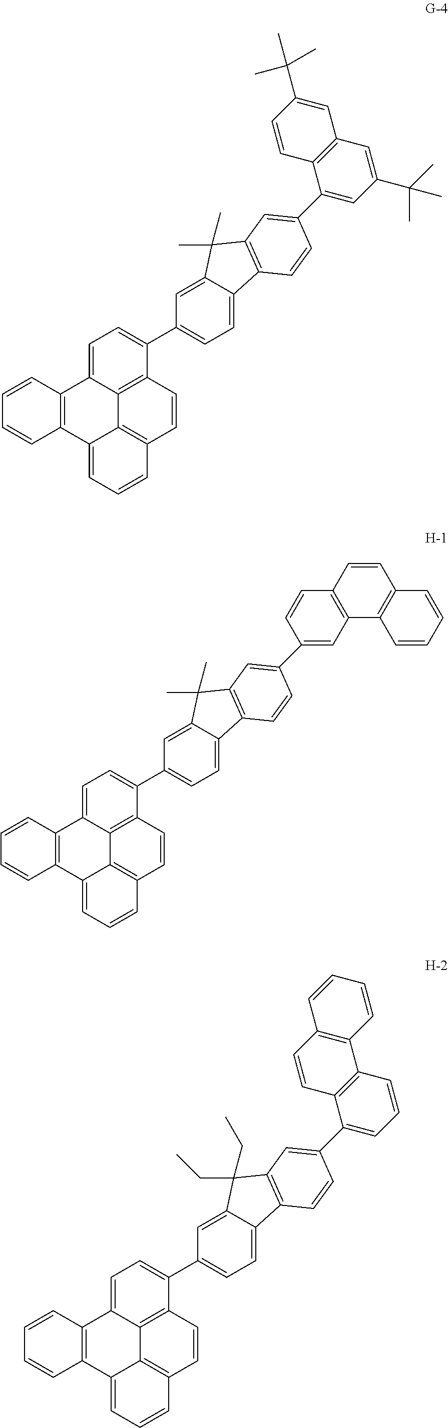

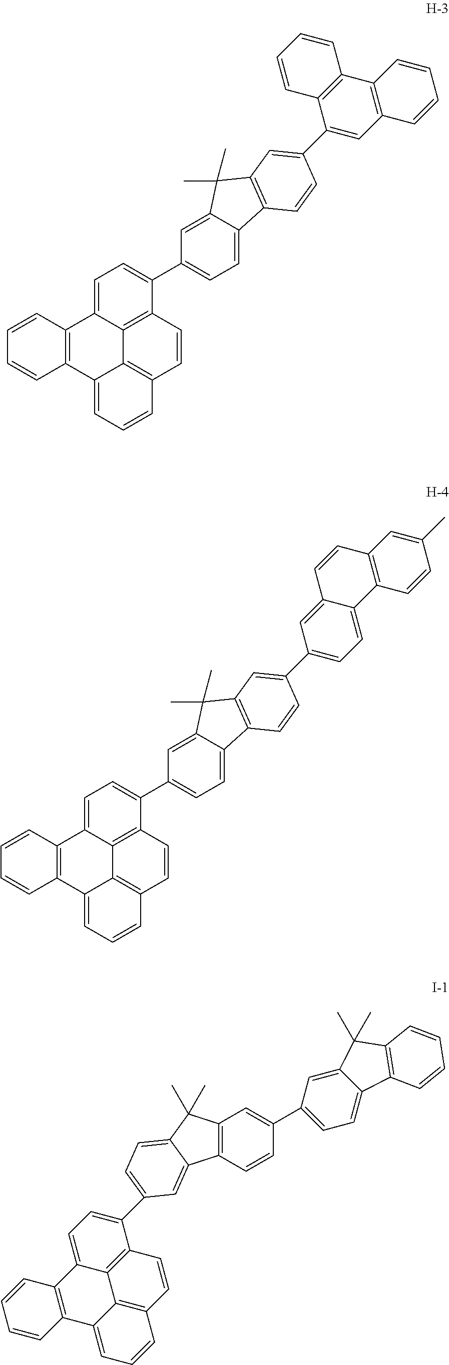

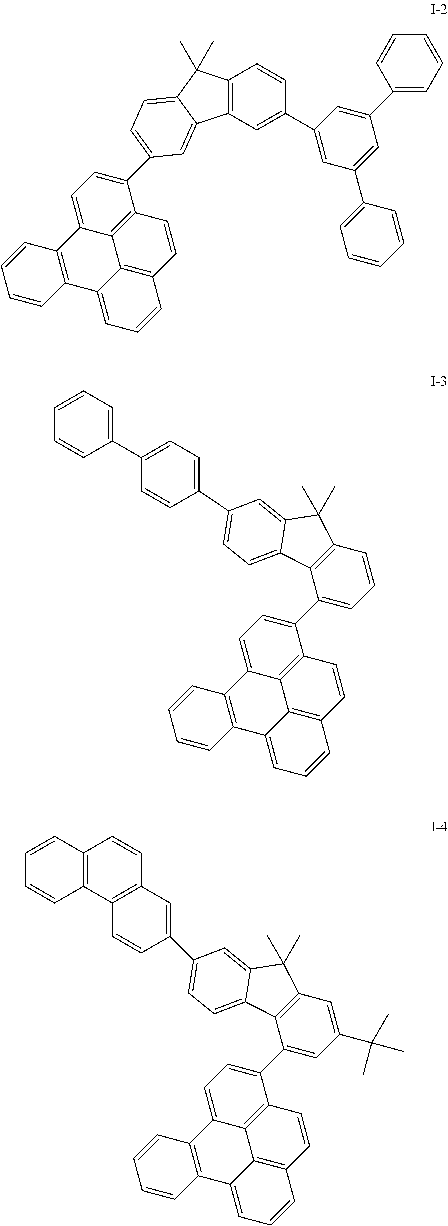

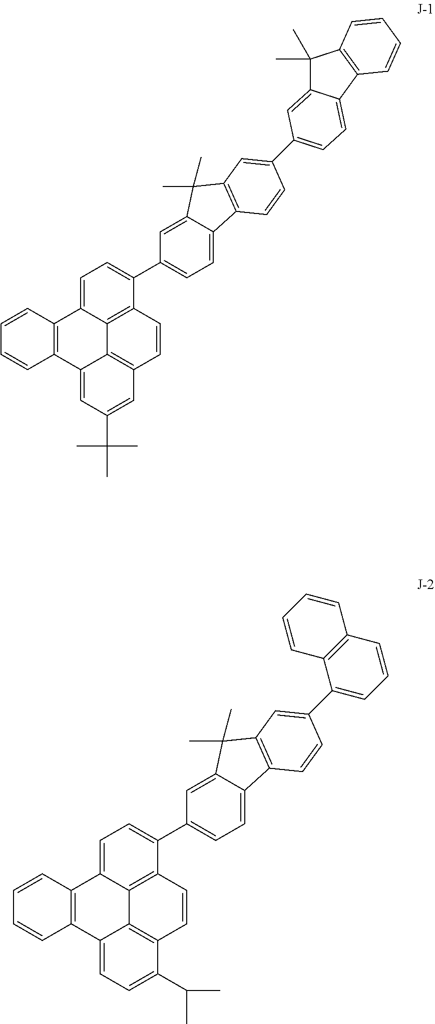

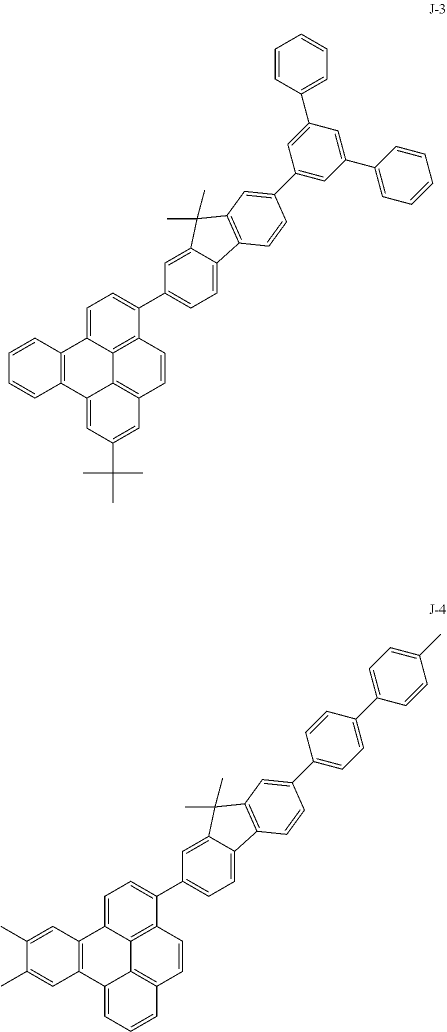

The benzopyrene compounds shown in Group C are those where Ar in formula [1] is a phenyl group. These compounds have small molecular weight, so sublimability is high, then these compounds sublimate at a low temperature. The phenyl group may have the alkyl group, such as a tert-butyl group, and a methyl group. The alkyl group makes the ionized potential of the benzopyrene compound low.

The benzopyrene compounds shown in Group D and E are those where Ar in formula [1] is a biphenyl group or a tert-phenyl group. These substituents make the mobility of the benzopyrene compound tunable. These substituents may have a substituent, such a tert-butyl group, a phenyl group, a secondary butyl group. The alkyl group such the tert-butyl group and the secondary butyl group make the ionized potential of the benzopyrene low.

The benzopyrene compounds shown in Group F are those where Ar in formula [1] is a fluorenyl group. The benzopyrene compounds shown in Group F give the stable amorphous film. The benzopyrene compounds shown in Group F has 2 fluorenyl groups, so the compounds has low ionized potential. 9,9′-positions of the fluorenyl group which correspond to the Ar are each independently selected from an alkyl group having 1 to 4 carbon atoms, such as methyl groups, ethyl groups, iso-propyl groups, n-propyl groups, sec-butyl groups, and tert-butyl groups, and among them, the methyl group is preferable.

The benzopyrene compounds shown in Group G and H are those where Ar in formula [1] is naphtyl groups or phenanthryl groups. The benzopyrene compounds shown in Group G and H keep their amorphous film in shape. And the benzopyrene compounds shown in Group G and H are those where Ar in formula [1] has high flatness in their molecules, so that the mobility of the electron or hole is high. These naphtyl groups or phenanthlyl groups may have the substituent, such as tert-butyl groups or methyl groups.

The benzopyrene compounds shown in Group I are those where Ar in formula [1] is fluorenyl groups and the fluorenyl group bonds the benzopyrene at 3- or 4-position. So, in the benzopyrene compounds shown in Group I, conjugation is broken (does not exist) among the benzopyrene backbone and the fluorene portion, as a result, the benzopyrene compounds shown in Group I has wide band gap compared with the benzopyrene where 2-position of the fluorenyl group bonds to the benzopyrene backbone. And the benzopyrene compounds shown in Group I has high solubility because molecular flatness of the benzopyrene compounds shown in Group I is low.

The benzopyrene compounds shown in Group J are those where at least one of R1 to R11 in formula [1] is alkyl groups. These alkyl groups make the ionized potential of the benzopyrene compounds shown in Group J low.

Specifically, at least one of R4, R5, R8, R9 of the formula [1] and [2] is an alkyl group, more specifically one of a tert-butyl group, an iso-propyl group, and a methyl group.

The benzopyrene compound according to aspects of the present invention is applied not only to the organic light-emitting device, but also to others, i.e., an internal labeling for living body or a filter film.

(Description of the Organic Light-Emitting Device which has the Benzopyrene Compound According to Aspects of the Present Invention)

An organic light-emitting device of this embodiment has a pair of electrodes and an organic compound layer provided therebetween. The organic compound layer has the benzopyrene compound of the present invention, as seen in formula [1]. The pair of electrodes is for example, an anode and a cathode.

The organic compound in the light-emitting layer emits light by injection of electrons and holes through the pair of electrodes.

Examples of the organic light-emitting device produced using the benzopyrene compound according to aspects of the present invention include those having a configuration composed of an anode, a light-emitting layer, and a cathode provided in this order on a substrate. Other examples of the organic light-emitting device include those having a configuration where an anode, a hole-transporting layer, an electron-transporting layer, and a cathode are provided in this order; These types of multi-layer examples merely show quite basic device configurations, and the organic light-emitting device using the benzopyrene compound according to aspects of the present invention is not limited thereto.

Other examples of the organic light-emitting device include those having a configuration where an anode, a hole-transporting layer, a light-emitting layer, an electron-transporting layer, and a cathode are provided in this order; those having a configuration where an anode, a hole-injecting layer, a hole-transporting layer, a light-emitting layer, an electron-transporting layer, and a cathode are provided in this order; and those having a configuration where an anode, a hole-transporting layer, a light-emitting layer, a hole/exciton-blocking layer, an electron-transporting layer, and a cathode are provided in this order.

Examples of the organic light-emitting device produced using the benzopyrene compound according to aspects of the present invention include those having other configurations. For example the organic light-emitting device produced using the benzopyrene compound according to aspects of the present invention include the lamination order from the anode to the cathode of this configuration is arranged inversely with respect to that of the 5 configurations which are described above.

The organic compound layer which has the benzopyrene compound according to aspects of the present invention, as seen in formula [1], is preferably the light-emitting layer. The light-emitting layer may consist of the sole benzopyrene compound according to aspects of the present invention, as seen in formula [1]. The light-emitting layer may have a host material and a guest material.

In this case, the benzopyrene compound according to aspects of the present invention, as seen in formula [1], is preferably the host material.

The host material has larger weight ratio that of the guest material.

The amount of the guest material, which is the auxiliary component, relative to the total weight of the emission layer is 0.1 wt. % or more and 30 wt. % or less and preferably 0.5 wt. % or more and 10 wt. % or less.

In the organic light-emitting device according to the embodiment, in addition to the compound according to aspects of the present invention, for example, a hole-injecting material, hole-transporting material, host material, guest material, electron-injecting material, or electron-transporting material can be optionally used. These materials may be a low-molecular compound whose molecular weight is a few thousand or a high-molecular compound whose number average molecular weight is from a few thousand to a few million.

Examples of these compounds are shown below.

As the hole-injecting or transporting material, a material having high hole mobility can be used. Examples of the low- or high-molecular material having hole-injecting or transporting ability include, but not limited to, triarylamine derivatives, phenylenediamine derivatives, stilbene derivatives, phthalocyanine derivatives, porphyrin derivatives, poly(vinylcarbazole), poly(thiophene), and other electrically conductive polymers.

Examples of the host material include, but not limited to, triarylamine derivatives, phenylene derivatives, fused ring aromatic compounds (e.g., naphthalene derivatives, phenanthrene derivatives, fluorene derivatives, and chrysene derivatives), organic metal complexes (e.g., organic aluminum complexes such as tris(8-quinolinolate)aluminum, organic beryllium complexes, organic iridium complexes, and organic platinum complexes), and polymer derivatives such as poly(phenylenevinylene)derivatives, poly(fluorene)derivatives, poly(phenylene)derivatives, poly(thienylenevinylene)derivatives, and poly(acetylene)derivatives.

The guest material is, for example, Ir complex, Pt complex. These are phosphorescent emitting compounds. In case of Ir complex, the ligand is preferably the phenyl isoquinoline portion.

The electron-injecting or transporting material is appropriately selected by considering, for example, the balance with the hole mobility of the hole-injecting or transporting material. Examples of the material having electron-injecting or transporting ability include, but not limited to, oxadiazole derivatives, oxazole derivatives, pyrazine derivatives, triazole derivatives, triazine derivatives, quinoline derivatives, quinoxaline derivatives, phenanthroline derivatives, and organic aluminum complexes.

As the anode material, a material having a higher work function is used. Examples of the material include simple metals such as gold, platinum, silver, copper, nickel, palladium, cobalt, selenium, vanadium, and tungsten; alloys of these simple metals; and metal oxides such as tin oxide, zinc oxide, indium oxide, indium tin oxide (ITO), and indium zinc oxide. In addition, electrically conductive polymers such as polyaniline, polypyrrole, and polythiophene can be used.

These electrode materials may be used alone or in combination. The anode may have a monolayer structure or a multilayer structure.

In contrast, as the cathode material, a material having a lower work function is used. Examples of the material include alkali metals such as lithium; alkaline earth metals such as calcium; simple metals such as aluminum, titanium, manganese, silver, lead, and chromium; and alloys of these simple metals, such as magnesium-silver, aluminum-lithium, and aluminum-magnesium. In addition, metal oxides such as indium tin oxide (ITO) can be used. These electrode materials may be used alone or in combination. The cathode may have a monolayer structure or a multilayer structure.

In the organic light-emitting device according to the embodiment, a layer containing the fused multi-ring compound according to the embodiment and other layers of other organic compounds are formed by the following methods. For example, a layer is formed by vacuum vapor deposition, ionized vapor deposition, sputtering, plasma coating, or known coating such as spin coating, dipping, a casting method, an LB method, or an ink-jetting method of a compound dissolved in an appropriate solvent.

In the case of forming a layer by vacuum deposition, solution coating, or the like, crystallization hardly occurs, and the resulting layer shows excellent stability for a long time. In addition, in coating, a film can be formed in combination with an appropriate binder resin.

Examples of the binder resin include, but not limited to, polyvinyl carbazole resins, polycarbonate resins, polyester resins, ABS resins, acrylic resins, polyimide resins, phenol resins, epoxy resins, silicone resins, and urea resins.

These binder resins may be used alone as a homopolymer or a copolymer or in combination of two or more thereof. In addition, known additives such as a plasticizer, an antioxidant, or a UV absorber may be optionally used together with the resin binder.

Use of organic light-emitting device according to the embodiment.

### (Applications of the Electroluminescent Device)

The organic light-emitting device according to the embodiment can be used as a component of a display apparatus or a lighting apparatus. Other examples of use include exposure light sources of electrophotographic image forming apparatuses, backlights of liquid crystal display apparatuses, and white light sources. The organic light-emitting device may further include a color filter.

The display apparatus according to the embodiment includes the organic light-emitting device according to the embodiment in a display section. This display section includes a plurality of pixels.

The pixels each include the organic light-emitting device according to the embodiment and an active device for controlling luminance of the organic light-emitting device. Examples of the active device include switching devices and amplifier devices for controlling luminance. An example of these active devices is a transistor. The anode or the cathode of the organic light-emitting device is connected to the active device.

Here, the display apparatus can be used as an image display apparatus of, for example, a PC.

The display apparatus may be an image display apparatus that includes an image input section for inputting image information from, for example, an area CCD, a linear CCD, or a memory card and displays the input image on the display section.

The display section of an image pickup apparatus or ink-jet printer may have a touch panel function. The touch panel function may be driven by any drive system.

The display apparatus may be used in the display section of a multi-functional printer.

The lighting apparatus is an apparatus for lighting, for example, a room. The lighting apparatus may emit light of white, neutral white, or any color from blue to red.

In the embodiment, the white color has a color temperature of about 4200 K, and the neutral white color has a color temperature of about 5000 K.

The lighting apparatus according to the embodiment includes the organic light-emitting device according to the embodiment and a converter circuit connected to the device. The lighting apparatus may have a color filter.

The converter circuit according to the embodiment converts AC voltage to DC voltage.

The electrophotographic image forming apparatus such as a laser printer or copying machine may have the light source which comprises the organic light emitting device according to the embodiment.

The light source is for exposing light to the photosensitive drum to obtain electrostatic latent image. The light source may have one or plurality of the organic light-emitting device. In case that the light source has a plurality of the organic light-emitting device, the light source also has controlling means to switch the emission and non/emission of the organic light-emitting device. A plurality of the organic light-emitting device is located in a line along the longitudinal direction of the photosensitive drum. A lends may be located between the organic light-emitting device and the photosensitive drum.

A display apparatus including the organic light-emitting device according to the embodiment will now be described with reference to FIGURE.

FIGURE is a schematic cross-sectional view of a display apparatus having organic light-emitting devices according to the embodiment and TFT devices as an example of transistors connected to the organic light-emitting devices.

The display apparatus includes a substrate 10 such as a glass substrate and a moisture-proof film 11 provided on the substrate 10 for protecting the TFT devices or the organic compound layer. Reference numeral 12 denotes a metal gate electrode, reference numeral 13 denotes a gate insulating film, and reference numeral 14 denotes a semiconductor layer.

The TFT device 17 includes a semiconductor layer 14, a drain electrode 15, and a source electrode 16. An insulating film 18 is provided on the TFT device 17. The anode 20 of the organic light-emitting device and the source electrode 16 are connected to each other via a contact hole 19.

The display apparatus according to the embodiment is not limited to this configuration as long as either the anode or the cathode is connected to either the source electrode or the drain electrode of the TFT device.

In FIGURE, the organic compound layer 21 of a multilayer is shown as one layer. The organic compound layer may be composed of a plurality of layers. Furthermore, a first protective layer 23 and a second protective layer 24 are provided on the cathode 22 to prevent the organic light-emitting device from deteriorating.

The display apparatus according to the embodiment may have an MIM device instead of the transistor as a switching device.

The transistor can be the one formed on a single-crystalline silicon wafer.

The configuration is selected depending on the resolution. For example, in a resolution of about 1-inch QVGA, the organic light-emitting devices can be provided in a Si substrate.

### EXAMPLES

The present invention will be described in detail by the following examples, but is not limited thereto.

### Example 1

### Synthesis of Example Compound F-1

Example Compound F-1 was synthesized by a synthesis scheme shown below:

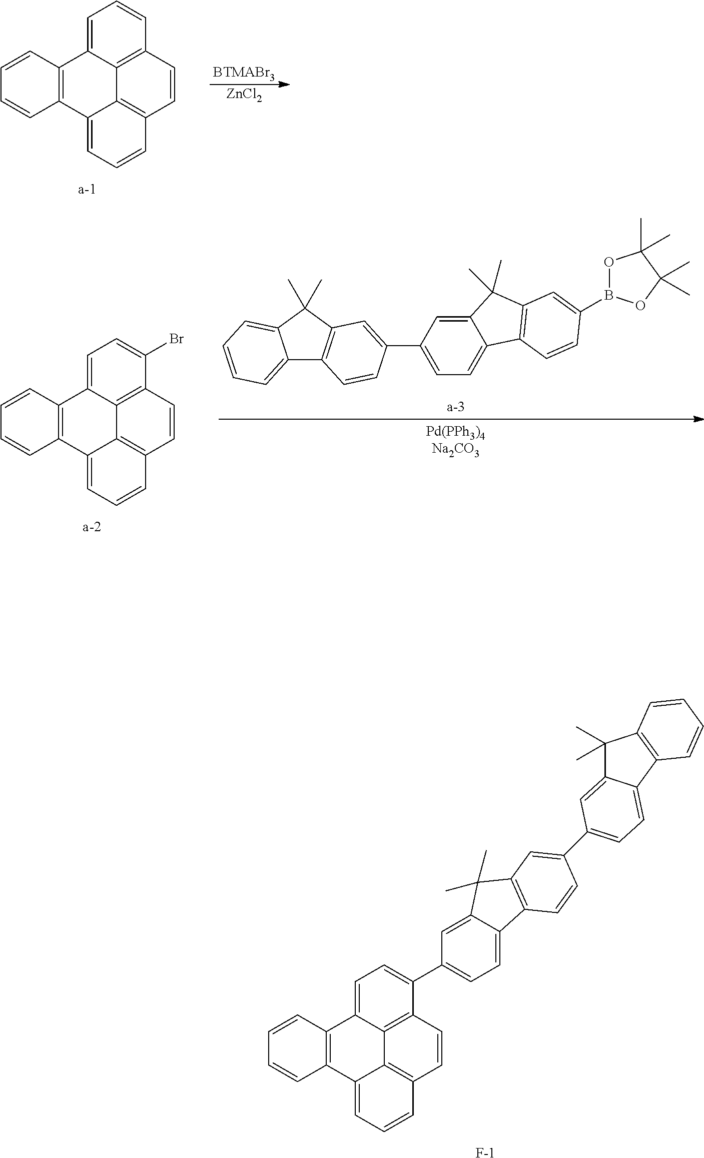

### Synthesis of Compound a-2

In a 300-mL three-neck flask, 0.900 g (3.57 mmol) of compound a-1, 1.389 g (3.56 mmol) of benzyltrimethylammoniumtribromide, 0.486 g(3.57 mmol) of zinc chloride, and 60 mL of chloroform were placed, and stirred for 3 hours at room temperature. After the reaction, the organic layer was poured into 100 mL of water. The organic layer was extracted with toluene and was dried over anhydrous sodium sulfate. The dried organic layer is purified by silica gel column (elunet: mixture of toluene and heptane) and 0.963 g (yield: 96%) of a white solid was obtained.

### Synthesis of Compound F-2

In a 300-mL three-neck flask, 0.331 g (1.00 mmol) of compound a-2, 0.564 g (1.10 mmol) of compound a-3, 1.06 g(10.0 mmol) of sodium carbonate, 20 mL of toluene 10 ml of ethanol and 20 ml of water were placed, and were stirred in N2 atmosphere at room temperature. 57.8 mg of tetrakis(triphenylphosphine)palladium(0) was added into the mixture. Reaction was carried at 80° C. for 5 hours. After the reaction, the organic layer was extracted with toluene and was dried over anhydrous sodium sulfate. The dried organic layer is purified by silica gel column (elunet: mixture of toluene and heptane) and 0.541 g (yield: 85%) of a yellowish white solid was obtained.

By mass spectrometry, M+ of Example Compound F-1, 636, was confirmed.

The structure of Example Compound A-2 was confirmed by 1H NMR measurement.

1H NMR(CDCl3,400 MHz) σ(ppm): 8.98(d,1H), 8.94(d,1H), 8.91 8.86(m,2H), 8.26(d,1H), 8.17(d,1H), 8.10(d,1H), 8.06(d,1H), 8.02(d,1H), 7.94(d,1H), 7.90(d,1H), 7.84(d,1H), 7.82 7.67(m,8H), 7.64(d,1H), 7.48(d,1H), 7.39 7.33(m,2H), 1.67(s,6H), 1.59(s,6H)

The band gap of this compound is 2.99 eV. And the T1 level of this compound is 555 nm.

The band gap from the absorption edge of a spin-coated film on the glass substrate which is obtained bu the 0.1 wt. % solution of the compound in toluene solution is measured from the visible-ultraviolet absorption spectrum. In this example, The measurement was performed with a spectrometer U-3010 manufactured by Hitachi, Ltd.

T1 was determined as the first emission peak by cooling a toluene solution (1 10-4 mol/L) to 77K and measuring the phosphorescence emission spectrum at an excitation wavelength of 350 nm. The measurement was performed with a spectrometer U-3010 manufactured by Hitachi, Ltd.

### Example 2

### Synthesis of Example Compound G-1

Example Compound G-1 was synthesized as in Example 1 except that compound a-6 was used instead of compound of a-3.

By mass spectrometry, M+ of Example Compound G-1, 569, was confirmed.

The band gap of this spin coated film is 2.97 eV.

And the T1 level of this compound is 558 nm.

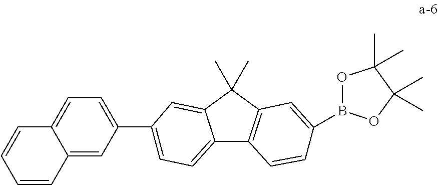 [SMILES: CC1(C)c2cc(B3OC(C)(C)C(C)(C)O3)ccc2-c2ccc(-c3ccc4ccccc4c3)cc21]

### Example 3

### Synthesis of Example Compound E-2

Example Compound E-2 was synthesized as in Example 1 except that compound a-4 was used instead of compound of a-3.

By mass spectrometry, M+ of Example Compound E-2, 659, was confirmed.

The band gap of this spin coated film is 3.02 eV.

And the T1 level of this compound is 550 nm.

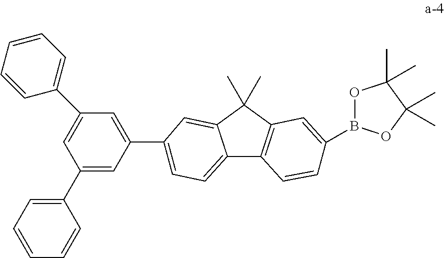 [SMILES: CC1(C)c2cc(B3OC(C)(C)C(C)(C)O3)ccc2-c2ccc(-c3cc(-c4ccccc4)cc(-c4ccccc4)c3)cc21]

The Band gap(eV) and T1(nm) of Benzo[e]pyrene, compounds F-1, G-1, and E-2 is described in the table below:

| | Band Gap | T1 |
|---|---|---|
| Compounds | eV | nm |
| Benzo[e]pyrene | 3.30 | 538 |
| F-1 | 2.99 | 555 |
| E-2 | 3.02 | 550 |
| G-1 | 2.97 | 558 |

### Example 4

### Synthesis of Example Compound D-2

Example Compound D-2 was synthesized as in Example 1 except that compound a-5 was used instead of compound of a-3.

By mass spectrometry, M+ of Example Compound D-2, 596, was confirmed.

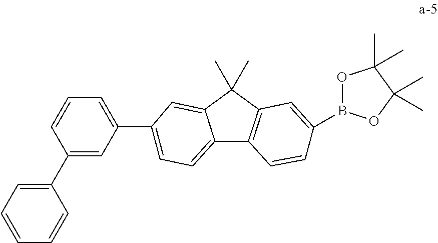 [SMILES: CC1(C)c2cc(B3OC(C)(C)C(C)(C)O3)ccc2-c2ccc(-c3cccc(-c4ccccc4)c3)cc21]

### Example 5

### Synthesis of Example Compound F-2

Example Compound F-2 was synthesized as in Example 1 except that compound a-7 was used instead of compound of a-3.

By mass spectrometry, M+ of Example Compound F-2, 636, was confirmed.

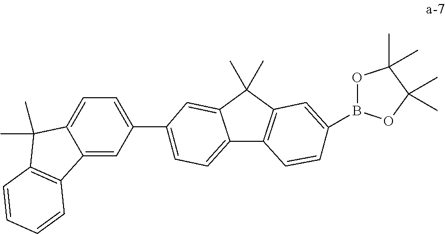

### Example 6

### Synthesis of Example Compound E-3

Example Compound E-3 was synthesized as in Example 1 except that compound a-8 was used instead of compound of a-3.

By mass spectrometry, M+ of Example Compound E-3, 784, was confirmed.

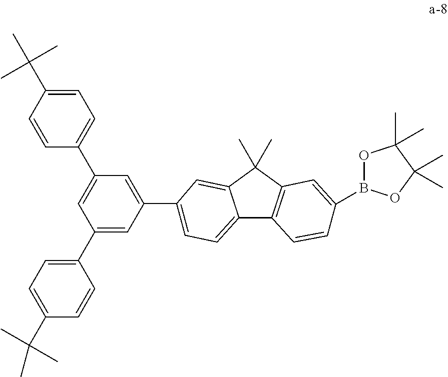 [SMILES: CC(C)(C)c1ccc(-c2cc(-c3ccc(C(C)(C)C)cc3)cc(-c3ccc4c(c3)C(C)(C)c3cc(B5OC(C)(C)C(C)(C)O5)ccc3-4)c2)cc1]

### Example 7

### Synthesis of Example Compound J-1

Example Compound J-1 was synthesized as in Example 1 except that compound b-1 was used instead of compound of a-1.

By mass spectrometry, M+ of Example Compound J-1, 692, was confirmed.

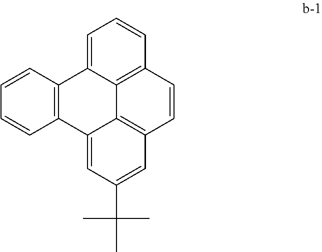 [SMILES: CC(C)(C)c1cc2ccc3cccc4c5ccccc5c(c1)c2c34]

### Example 8

In this example, an organic light-emitting device was produced by the following method.

A film of ITO was formed on a glass substrate by sputtering as an anode having a thickness of 120 nm, and the resulting product was used as a transparent electrically conductive support substrate (ITO substrate). The resulting product was washed by ultrasonic cleaning with acetone and then isopropyl alcohol (IPA) and then washed by boiling in IPA, followed by drying. Furthermore, the surface of this substrate was washed with UV/ozone and the substrate was used as transparent electro conductive substrate.

On this ITO substrate, organic compound layers and electrode layers shown below were successively formed by resistance heating vacuum vapor deposition in a vacuum chamber of 10-5 Pa.

Hole transporting layer (40 nm): compound c-1 Electron-blocking layer (10 nm): compound c-2 Emitting layer (30 nm): guest: compound c-5 (weight ratio: 4.0%), host: compound F-1 (weight ratio: 96.0%), Hole-blocking layer (10 nm): compound c-4 Electron-transporting layer (50 nm): compound c-5 Metal electrode layer 1 (0.5 nm): LiF Metal electrode layer 2 (150 nm): Al

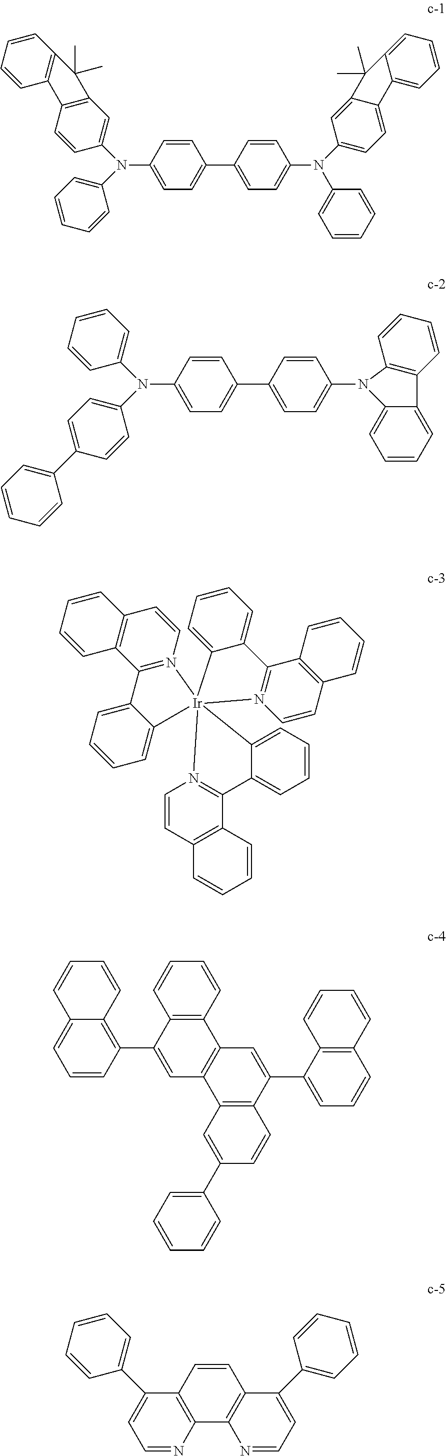

When a voltage of 5.0 V was applied the organic electro luminescent device, red light emission having a 1850 cd/m2 of emission luminosity, and having the CIE chromaticity coordinates (x, y) were (0.32, 0.68) was observed.

In addition, when a voltage was being applied to the organic electroluminescent device for 100 h, keeping a current density 100 mA/cm2 in N2 atmosphere, the reduction rate to an initial luminance was less than 20% even after 400 hours passed.

### Example 9

An organic light-emitting device was produced as in Example 8 except that compound E-2 was used instead of compound of F-1.

When a voltage of 5.0 V was applied the organic electro luminescent device, red light emission having a 1780 cd/m2 of emission luminosity, and having the CIE chromaticity coordinates (x, y) were (0.32, 0.68) was observed.

In addition, when a voltage was being applied to the organic electroluminescent device for 100 h, keeping a current density 100 mA/cm2 in N2 atmosphere, the reduction rate to an initial luminance was less than 25% even after 400 hours passed.

### Example 10

An organic light-emitting device was produced as in Example 8 except that compound G-1 was used instead of compound of F-1.

When a voltage of 5.0 V was applied the organic electro luminescent device, red light emission having a 2030 cd/m2 of emission luminosity, and having the CIE chromaticity coordinates (x, y) were (0.32, 0.68) was observed.

In addition, when a voltage was being applied to the organic electroluminescent device for 100 h, keeping a current density 100 mA/cm2 in N2 atmosphere, the reduction rate to an initial luminance was less than 30% even after 400 hours passed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-128281, filed Jun. 5, 2012, which is hereby incorporated by reference herein in its entirety.

What is claimed is:

1. A benzo pyrene compound represented by the following formula [1]: 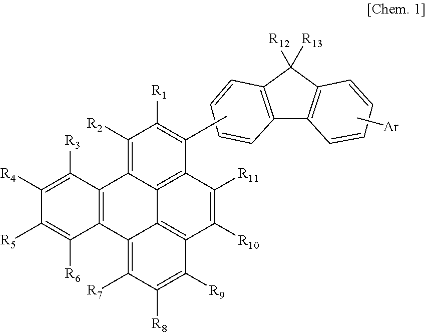
wherein in formula [1], R1 to R13 each independently indicate a hydrogen atom and an alkyl group having 1 to 4 carbon atoms;
Ar is selected from a group of a phenyl group, a biphenyl group, a terphenyl group, a fluorenyl group, a naphthyl group and a phenanthlyl group; and
the hydrogen atom of Ar may be substituted by an alkyl group having 1 to 4 carbon atoms.

2. A benzo pyrene compound according to claim 1, wherein the bezopyrene compound is represented by the following formula [2]:

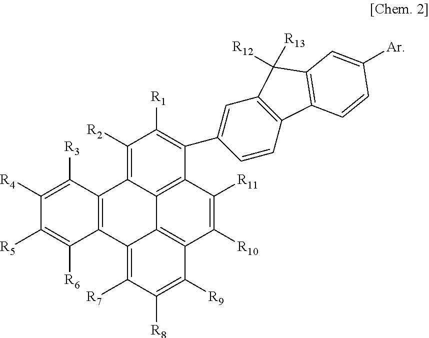

3. A benzo pyrene compound according to claim 1, wherein Ar is selected from a group of the biphenyl group, the terphenyl group, the fluorenyl group, and the naphthyl group.

4. A benzo pyrene compound according to claim 3, wherein R12 and R13 are methyl groups.

5. An organic light-emitting device comprising:
a pair of electrodes
an organic compound layer provided therebetween,
wherein the organic compound layer has the benzopyrene compound according to claim 1.

6. An organic light-emitting device according claim 5, wherein the organic compound layer is a light emitting layer, and has a host material and a guest material.

7. An organic light-emitting device according claim 6, wherein the host material is benzopyrene compound.

8. An organic light-emitting device according claim 7, wherein the guest material is a phosphorescent material which emits red light.

9. An organic light-emitting device according claim 5, wherein the anode has a metal oxide.

10. An organic light-emitting device according claim 5, wherein the cathode has a metal oxide.

11. An image forming apparatus comprising:
a plurality of the pixels,
wherein each pixel includes the organic light-emitting device according to claim 6, and an active device for controlling luminance of the organic light-emitting device.

12. The lighting apparatus comprising;
the organic light-emitting device according to claim 6, and a converter circuit connected to the organic light-emitting device.

13. The lighting apparatus comprising according to claim 12;
the lighting apparatus emits light of white or neutral white.

14. An image forming apparatus comprising;
a photosensitive drum, and
a light source for exposing light to the photosensitive drum to obtain electrostatic latent image,
wherein the light source has one or a plurality of the organic light-emitting devices according to claim 5.

15. The image forming apparatus according to claim 14,
wherein the light source has a plurality of the organic light-emitting devices,
the light source has controlling means to switch the emission and non/emission of each organic light-emitting device, and
the plurality of organic light-emitting devices is located in a line along the longitudinal direction of the photosensitive drum.
